(19) United States
(12) Patent Application Publication
(10) Pub. No.: US 2024/0213953 A1
(43) Pub. Date: Jun. 27, 2024

(54) BALANCE-SPRING PIEZOELECTRIC RESONATOR, IN PARTICULAR FOR A TIMEPIECE ROTARY MOTOR

(71) Applicant: The Swatch Group Research and Development Ltd, Marin (CH)

(72) Inventors: Mohammad Hussein KAHROBAIYAN, Boudevilliers (CH); Yvan FERRI, St-Aubin-sauges (CH); Alexandre DIDIER, Erlach (CH); Lionel PARATTE, Marin-Epagnier (CH); Jean-Jacques BORN, Morges (CH)

(73) Assignee: The Swatch Group Research and Development Ltd, Marin (CH)

(21) Appl. No.: 18/541,184

(22) Filed: Dec. 15, 2023

(30) Foreign Application Priority Data
Dec. 23, 2022 (EP) 22216423.8

(51) Int. Cl. H03H 9/13; G04F 5/06; H02N 2/12

(52) U.S. Cl. CPC H03H 9/13; G04F 5/063; H02N 2/12

(57) ABSTRACT

A piezoelectric resonator, in particular for a rotary piezoelectric motor, the resonator including a stationary base and an oscillating mass extending about a longitudinal axis, the oscillating mass being provided with at least one inertia-block, preferably two opposing inertia-blocks, wherein the resonator includes a flexible blade guide connecting the oscillating mass to the base, so that the oscillating mass can be oscillated about a centre of rotation in a pendulum movement, the flexible guide including at least one first flexible blade connected to the base and/or to the oscillating mass to allow the displacement of the oscillating mass relative to the base, the flexible blade guide including a spiral spring connected to the base and/or to the oscillating mass, the spiral spring including at least partially an electrically actuatable piezoelectric material to deform the spiral spring and oscillate the oscillating mass.

### TECHNICAL FIELD OF THE INVENTION

The invention relates to the technical field of the piezoelectric resonators, in particular for a rotary piezoelectric motor. The invention also relates to the technical field of timepieces provided with such a rotary piezoelectric motor.

### TECHNOLOGICAL BACKGROUND

The electric motors usually used in watchmaking are “Lavet” type rotary motors, which operate on electromagnetic physical principles. Such a motor generally includes a stator provided with coils and a magnetised rotor, which rotates by phase-shifted actuation of the coils.

However, these motors have a limited resistance to high magnetic fields. From a certain magnetic field value, the motor is blocked. In general, they are blocked when the magnetic field exceeds 2 mT.

Thus, in order to avoid this problem, it is necessary to design motors operating on other physical principles.

For example, there are electrostatic comb motors, such as that described in patent CH709512. But the combs take up space, and they consume more energy than “Lavet” type motors.

Motors based on the piezoelectric effect have also been developed, for example in patent EP0587031. But this is limited to the actuation of a date. Furthermore, its high energy consumption and the risk of premature wear do not allow driving a second hand, which generally requires the most energy.

### SUMMARY OF THE INVENTION

The aim of the present invention is to propose a piezoelectric resonator, in particular for a rotary piezoelectric motor, which can resist high electromagnetic fields, while keeping reduced energy consumption and volume.

To this end, the invention relates to a piezoelectric resonator, in particular for a rotary piezoelectric motor of a timepiece, the resonator comprising a stationary base and an oscillating mass extending about a longitudinal axis, the oscillating mass being provided with at least one inertia-block, preferably two opposing inertia-blocks.

The invention is remarkable in that it comprises a flexible blade guide connecting the oscillating mass to the base, so as to be able to oscillate the oscillating mass about a centre of rotation in a pendulum movement, the flexible guide comprising at least one first flexible blade connected to the base and/or to the oscillating mass to allow the displacement of the oscillating mass relative to the base, the flexible blade guide comprising a spiral spring connected to the base and/or to the oscillating mass, the spiral spring including at least partially an electrically actuatable piezoelectric material to deform the spiral spring and oscillate the oscillating mass.

A resonator having such a configuration allows providing a movement efficiently. Indeed, by actuating the piezoelectric material of the spiral spring, the latter is alternately contracted and stretched, such that the oscillating mass oscillates by pivoting on itself about a centre of rotation, thanks to the flexible blade of the flexible guide. Thus, the resonator produces an oscillatory movement of the oscillating mass, while consuming little energy, because the actuation of the flexible blade(s) requires less energy.

The oscillating movement can thus be transmitted to other mechanical parts according to the field of application of the piezoelectric resonator, for example to a motor gear wheel.

According to a particular embodiment of the invention, the flexible guide includes a second flexible blade connecting the oscillating mass to the base, the first flexible blade connecting the base to the oscillating mass.

According to a particular embodiment of the invention, the first flexible blade and the second flexible blade are uncrossed and extend from a central portion of the oscillating mass to eccentric portions of the base.

According to a particular embodiment of the invention, the first flexible blade and the second flexible blade are arranged to form an angle comprised between 30° and 150°, preferably between 60° and 130°, or even between 90° and 120°.

According to a particular embodiment of the invention, the spiral spring is connected to the oscillating mass to actuate the oscillation.

According to a particular embodiment of the invention, the flexible guide comprises two RCC type flexible pivots, the flexible guide being provided with an intermediate movable element, a first pair of flexible blades provided with the first flexible blade and a second flexible blade, the first pair of flexible blades connecting the base to the intermediate movable element, and a second pair of flexible blades, connecting the intermediate movable element to the oscillating mass.

According to a particular embodiment of the invention, the first flexible blade and the second flexible blade are uncrossed and move away from each other from the intermediate movable element to eccentric portions of the base.

According to a particular embodiment of the invention, the first flexible blade and the second flexible blade are arranged to form an angle comprised between 30° and 100°, preferably between 40° and 80°.

According to a particular embodiment of the invention, the first flexible blade and the second flexible blade are arranged axially symmetrically relative to each other.

According to a particular embodiment of the invention, the spiral spring is connected to the intermediate element and to the base, the spiral spring producing the oscillation of the intermediate element when actuated.

According to a particular embodiment of the invention, the spiral spring is arranged between the first pair of flexible blades and the second pair of flexible blades.

According to a particular embodiment of the invention, the spiral spring and the first pair of flexible blades are arranged to form an angle comprised between 60° and 120°, preferably between 80° and 100°.

According to a particular embodiment of the invention, the spiral spring and the second pair of flexible blades are arranged to form an angle comprised between 20° and 60°, preferably between 30° and 45°.

According to a particular embodiment of the invention, the flexible guide comprises two RCC type flexible pivots, the flexible guide being provided with an intermediate movable element, a pair of flexible blades provided with the first flexible blade, the pair of flexible blades connecting the intermediate movable element to the oscillating mass, the spiral spring connecting the base to the intermediate movable element, the flexible guide comprising a second spiral spring connecting the base to the intermediate movable element, the second spiral spring including an electrically actuatable piezoelectric material to deform the second spiral spring and oscillate the oscillating mass.

According to a particular embodiment of the invention, the first spiral spring and the second spiral spring are arranged to form an angle comprised between 80° and 160°, preferably between 100° and 140°, or even between 110° and 130°.

According to a particular embodiment of the invention, the first spiral spring and the second spiral spring are arranged axially symmetrically relative to each other.

According to a particular embodiment of the invention, the piezoelectric resonator is arranged substantially in the same plane.

According to a particular embodiment of the invention, the resonator is configured to oscillate the oscillating mass at the natural frequency of the resonator.

According to a particular embodiment of the invention, the resonator includes, preferably predominantly, a non-magnetic monocrystalline or polycrystalline material and having low conductivity, such as silicon, glass, ceramic or a metal, and obtained for example by a MEMS-type photo-lithographic micromachining process.

According to a particular embodiment of the invention, the flexible guide is made in one piece.

The invention also relates to a piezoelectric motor, in particular for a display device of a timepiece, comprising such a piezoelectric resonator.

According to a particular embodiment of the invention, the piezoelectric motor comprises at least one pawl, preferably two pawls, and a movable wheel, the pawl being mounted on the oscillating mass of the piezoelectric resonator, so as to rotate the movable wheel in a first direction when the oscillating mass performs its oscillations.

The invention further relates to a timepiece including a horological movement comprising a gear transmission configured to rotate at least one hand, and comprising such a piezoelectric motor arranged to actuate the gear transmission.

### BRIEF DESCRIPTION OF THE FIGURES

Other features and advantages will be clear from the following description, by way of indication and without limitation, with reference to the appended drawings, in which:

FIG. 1 schematically represents a top perspective view of a first embodiment of a piezoelectric resonator, in particular for a rotary motor, according to the invention,

FIG. 2 schematically represents a top perspective view of a second embodiment of a piezoelectric resonator, in particular for a rotary motor, according to the invention,

FIG. 3 schematically represents a top view of a third embodiment of a piezoelectric resonator, in particular for a rotary motor, according to the invention, and

FIG. 4 schematically represents a top perspective view of a rotary piezoelectric motor comprising such a resonator.

### DETAILED DESCRIPTION OF THE INVENTION

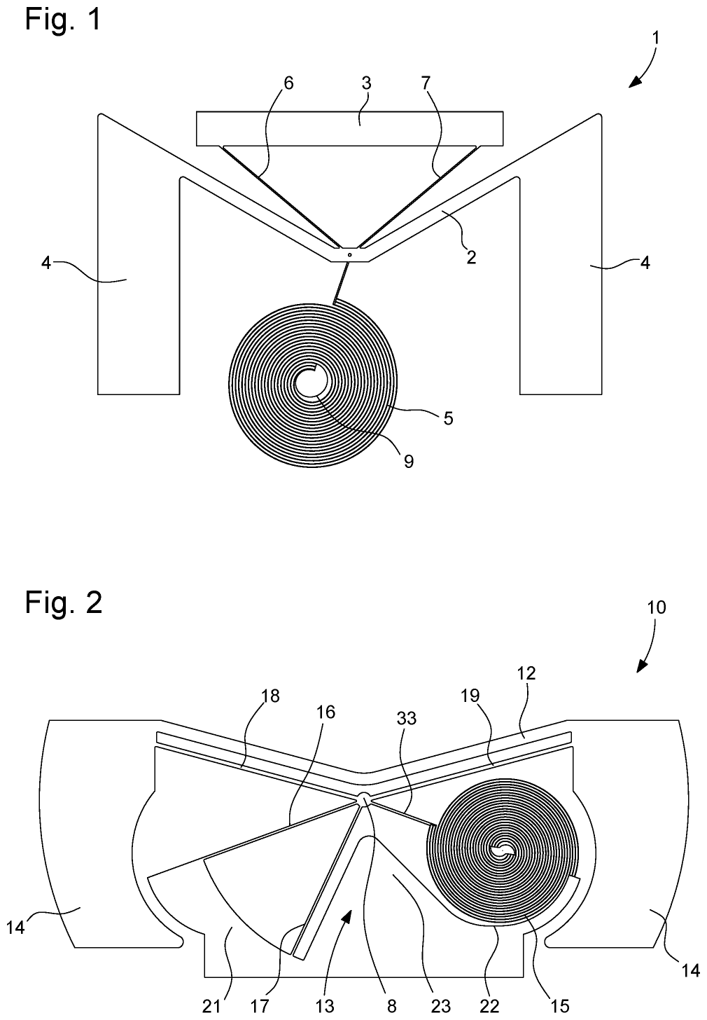

FIGS. 1 to 3 show different embodiments of a piezoelectric resonator 1, 10, 20, used in particular in a rotary motor. In particular, the motor can be used in a timepiece to actuate a display device comprising hands arranged to be displaced on a dial. The piezoelectric resonator 1, 10, 20 preferably extends substantially in one plane.

In FIG. 1, the first embodiment of piezoelectric resonator 1 comprises a base 3, which here has a substantially rectangular shape.

The piezoelectric resonator 1 also comprises an oscillating mass 2, here M-shaped. The oscillating mass 2 comprises a V-shaped main arm, at the ends of which two inertia-blocks 4 are arranged, here substantially straight, and extending opposite to the base 13.

The base 3 is arranged above the M. The oscillating mass 2 and the base 3 are preferably arranged in the same plane.

The resonator comprises a flexible blade guide connecting the oscillating mass 2 to the base 3, so that the oscillating mass 2 can be oscillated about a centre of rotation in a pendulum movement. The centre of rotation is arranged substantially in the middle of the oscillating mass 2, that is to say in the middle of the arm, preferably in the centre of mass of the oscillating mass 2.

The flexible guide comprises two flexible blades. A first flexible blade 6 and a second flexible blade 7 are connected to the same central portion of the oscillating mass 2, here at the inner top of the M, and form an RCC (Remote Center of Compliance) type pivot.

The first flexible blade 6 and the second flexible blade 7 are also connected to two opposing eccentric portions of the base 3, here at the corners of the rectangle.

The first flexible blade 6 and the second flexible blade 7 are uncrossed and extend from the inside of the oscillating mass 2 to the base 3.

The first flexible blade 6 and the second flexible blade 7 are arranged to form a non-zero angle therebetween, the angle being comprised between 30° and 150°, preferably between 60° and 130°, or even between 90° and 120°.

According to the invention, the flexible blade guide further comprises a spiral spring 5 connected to the oscillating mass 2. The spiral spring 5 is arranged on the other side of the M relative to the base 3.

The spiral spring 5 comprises several elastic coils. The spiral spring 5 comprises an inner end connected to a fixed blom stud 18, and an outer end extending by a substantially rectilinear segment connected to the intermediate mobile 8.

The spiral spring 5 includes at least partially an electrically actuatable piezoelectric material to deform it and oscillate the oscillating mass 2. The piezoelectric material is preferably arranged along the entire length of the spiral spring 5. The spiral spring 5 comprises, for example, a layer of piezoelectric material sandwiched between two electrode layers.

The electrode layers are themselves arranged above a one-piece structural support material, for example monocrystalline or polycrystalline silicon, such as quartz, glass, metal, etc. . . . .

In order to actuate the coiled blade, the stationary blom stud 9 comprises electrical contacts connected to the electrode layers to receive an electrical voltage and actuate the piezoelectric layers of the spiral spring 5.

The piezoelectric layers preferably include a crystalline or polycrystalline material, for example solid ceramic (for potassium sodium niobate) or of the PZT type (for lead zirconate titanate).

The activation is produced with an alternating voltage. Thus, by electrically activating the layers of piezoelectric material, the spiral spring 5 is alternately contracted and stretched in a rotational movement about its centre, in order to produce a rotary displacement of the oscillating mass 2 via the intermediate element 8. The oscillation is produced at a certain frequency, preferably at the resonance frequency of the resonator 1.

The piezoelectric layers arranged over the entire surface of the spiral spring 5 considerably increase the efficiency of the actuator, relative to a simple flexible and straight blade occupying the same space.

The oscillating mass 2 is guided in its movement by the two flexible blades 6, 7 of the flexible guide forming an RCC type pivot, so as to perform a pendulum movement about a centre of rotation. Thus, the oscillating mass 2 oscillates and the two inertia-blocks 4 are displaced laterally at a certain frequency, preferably the natural frequency of the resonator 1. The oscillating mass 2 performs oscillations about the centre of rotation located at the centre of the intermediate movable element 8.

In the second embodiment of FIG. 2, the piezoelectric resonator 10 comprises a base 13, which here has two curved portions 21, 22 arranged on either side of a substantially triangular central portion 23, and extending to the oscillating mass 12.

The resonator 10 further comprises an oscillating mass 12. The oscillating mass 12 comprises a main arm at the ends of which two inertia-blocks 14 are arranged, extending on either side of the base 13. The arm is disposed tangentially to the apex of the triangle. The arm is substantially curved in the middle to form a space, for example, for a rotor of a motor. The oscillating mass 12 and the base 13 are preferably arranged in the same plane.

The resonator comprises a flexible blade guide connecting the oscillating mass 12 to the base 13, so that the oscillating mass 12 can be oscillated about a centre of rotation in a pendulum movement.

The flexible guide comprises a first RCC type pivot. Such a pivot comprises an intermediate movable element 8, a first pair of flexible blades 16, 17 connecting the base to the intermediate movable element 8, and a second pair of flexible blades connecting the intermediate movable element to the oscillating mass 12, and forming a second RCC type pivot.

The intermediate movable element 8 is a point element, small in size compared with the base 13 and the oscillating mass 12. The point element 8 has for example a cylindrical shape. Preferably, the centre of rotation is arranged substantially at the centre of the intermediate movable element 8.

The first pair of flexible blades comprises a first flexible blade 16 and a second flexible blade 17 connecting the base 13 to the intermediate movable element 8. Preferably, the first flexible blade 16 and the second flexible blade 17 are substantially straight.

The first flexible blade 16 and the second flexible blade 17 are uncrossed and move away from each other from the intermediate movable element 8 to the same first curved portion 21 of the base 13.

The first flexible blade 16 and the second flexible blade 17 are arranged to form an angle comprised between 30° and 100°, preferably between 40° and 80°.

The second pair of flexible blades includes a third flexible blade 18, and a fourth flexible blade 19 extending from the intermediate movable element 8 to the oscillating mass 12, more particularly at the top of the inertia-blocks 14, below the arm. The second pair of flexible blades forms a second RCC type pivot.

Thus, the flexible blades 16, 17 of the first pair of flexible blades extend on a side which is opposite to the flexible blades 18, 19 of the second pair.

The third flexible blade 18 and the fourth flexible blade 19 are arranged to form an angle comprised between 30° and 150°, preferably between 60° and 130°, or even between 90° and 120°.

According to the invention, the flexible guide further includes a spiral spring 15 including a piezoelectric material, which is substantially identical to the spiral spring 5 of the first embodiment of FIG. 1.

The spiral spring 15 is arranged between the base 13 and the intermediate movable element 8, in particular in the second curved portion 22 of the base 13. The spiral spring 15 is further connected to each of them by a straight segment 33 connected to the intermediate movable element 8 and to the inner end being connected to the base 13.

The spiral spring 15 and the first pair of flexible blades 16, 17, in particular the second flexible blade 17, are arranged to form an angle comprised between 60° and 120°, preferably between 80° and 100°. The spiral spring 5 and the second pair of flexible blades 18, 19, in particular the fourth flexible blade 19, are arranged to form an angle comprised between 20° and 60°, preferably between 30° and 45°.

In this embodiment, when the spiral spring 15 is actuated, it acts on the intermediate movable element 8, so as to oscillate it. The movement of the intermediate movable element 8 is guided by the first pair of flexible blades 16, 17.

The oscillation of the intermediate movable element 8 is transmitted to the oscillating mass 12, thanks to the second pair of flexible blades 18, 19.

Thus, the oscillating mass 12 oscillates about a centre of rotation arranged here at the centre of the intermediate element 8. The two inertia-blocks 14 are displaced laterally at a certain frequency, preferably the natural frequency of the resonator 10.

An RCC type double pivot allows increasing the amplitude of oscillation of the oscillating mass 12, thanks to the second pair of flexible blades 18, 19.

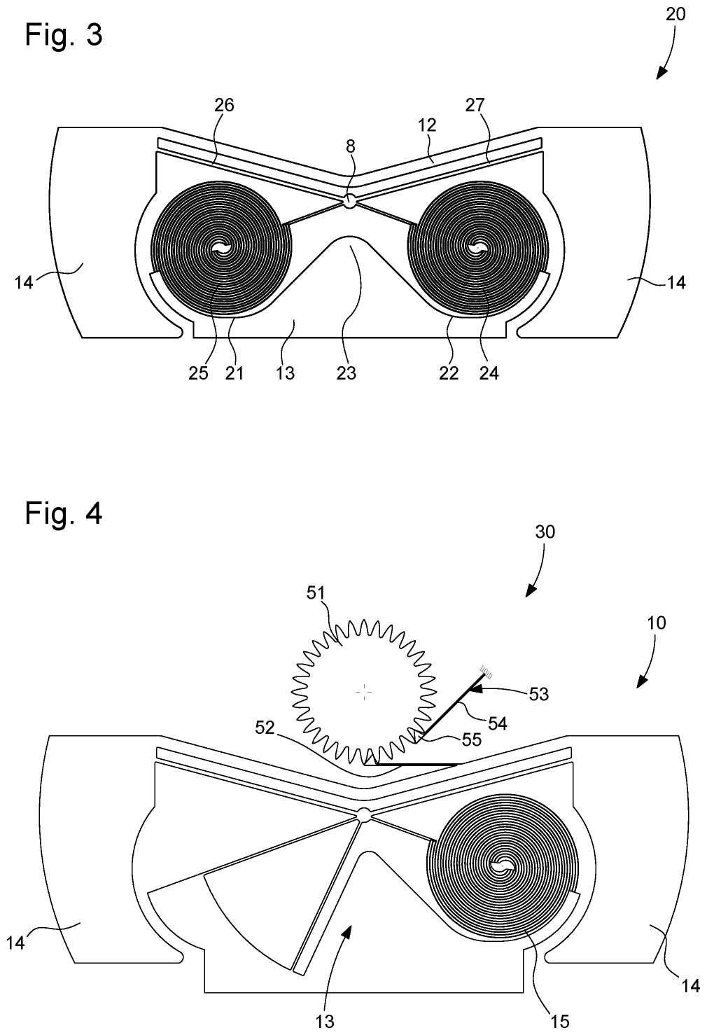

The third embodiment of a piezoelectric resonator 20 of FIG. 3, comprises a base 13, which here has two curved portions 21, 22 arranged on either side of a substantially triangular central portion 23, and extending towards the oscillating mass 12.

The oscillating mass 12 of the piezoelectric resonator 20 comprises a main arm at the ends of which two inertia-blocks 14 are arranged, extending on either side of the base 13. The arm is disposed tangentially to the apex of the triangle. The arm is substantially curved in the middle to get closer to the main apex of the triangle. The oscillating mass 12 and the base 13 are preferably arranged in the same plane.

The piezoelectric resonator 20 comprises a flexible blade guide 16, 17 connecting the oscillating mass 12 to the base 13, so that the oscillating mass 12 can oscillate about a centre of rotation in a pendulum movement.

The flexible guide comprises two RCC type pivots. Such a flexible guide generally comprises an intermediate movable element 8, a first pair of flexible blades 26, 27 connecting the intermediate movable element 8 to the oscillating mass 12, and a second pair of flexible blades connecting the base 13 to the intermediate movable element 8.

In this embodiment, the second pair of flexible blades of the second RCC type pivot are replaced by spiral springs.

The intermediate movable element 8 is a point element, small in size compared with the base 3 and the oscillating mass 2. The point element 8 has for example a cylindrical shape. Preferably, the centre of rotation is arranged at the centre of the intermediate movable element 8.

The first pair of flexible blades comprises a first flexible blade 26 connecting the intermediate movable element to the base 13, and a second flexible blade 27 connecting the base 13 to the intermediate movable element 8.

The flexible guide comprises a first spiral spring 5 and a second spiral spring 25. Each spiral spring 5, 25 is arranged between the base 3 and the intermediate movable element 8, in particular in each curved portion 21, 22 of the base 3.

The intermediate movable element 8 is further connected to each of them by a straight segment, the inner ends of each spiral spring being connected to the base 3. Thus, the first spiral spring 5 and the second spiral spring 25 extend on a side which is opposite to the flexible blades 26, 27 of the first pair.

The first spiral spring 24 and the second spiral spring 25 are arranged to form an angle comprised between 80° and 160°, preferably between 100° and 140°, or even between 110° and 130°. The first spiral spring 24 and the second spiral spring 25 are arranged axially symmetrically relative to each other.

The first spiral spring 24 and the second spiral spring 25 are substantially identical to the spiral springs of the first and second embodiments. Both spiral springs 24, 25 also include a piezoelectric material.

In this embodiment, the two spiral springs 5, 25 are actuated, preferably alternately. Thus, they act on the intermediate movable element 8, so as to oscillate it. The rotary movement of the intermediate movable element 8 is thus guided by the spiral springs 24, 25, as would an RCC type pivot with straight blades.

The oscillation of the intermediate movable element 8 is transmitted to the oscillating mass 12, thanks to the second pair of flexible blades 26, 27.

Thus, the oscillating mass 2 oscillates about a centre of rotation corresponding to the crossing point of the two flexible blades of the pairs, here at the intermediate element 8. The two inertia-blocks 14 are displaced laterally at a certain frequency.

An RCC type pivot increases the amplitude of oscillation of the oscillating mass 2, thanks to the second pair of flexible blades 9, 11.

The resonators 1, 10, 20, according to the previously described embodiments, include, preferably predominantly, a monocrystalline or polycrystalline material, such as silicon, glass, ceramic or a metal.

The resonators 1, 10, 20 are obtained, for example, by photo-lithographic micromachining processes of the MEMS (for micro-electro mechanical systems) type. The rigidity, elasticity and machining accuracy qualities of such materials give a high resonance performance to the resonators 1, 10, 20.

In addition, the non-magnetism and low conductivity characteristics of some of these materials allow obtaining an excellent resistance to high-value direct and alternating current magnetic fields.

Furthermore, the resonators 1, 10, 20 are configured to oscillate the oscillating mass 2, 12 at the natural frequency of the resonator 1, 10, 20. Thus, the energy consumption of the resonator is limited, in particular by increasing the angular travel of the oscillating mass.

FIG. 4 shows an embodiment of a rotary piezoelectric motor 30, in particular for a display device of a timepiece. The piezoelectric motor 30 can, in particular, be used in a timepiece to actuate a display device, such as hands arranged on a dial. The piezoelectric motor 30 is configured to be able to rotate and actuate a mechanical gear transmission of the display device.

The piezoelectric motor 30 comprises a piezoelectric resonator according to the invention, here the piezoelectric resonator 10 of the second embodiment of FIG. 2. The other piezoelectric resonator embodiments can also be used without this changing the operation of the piezoelectric motor 10. The piezoelectric resonator 10 is, for example, assembled to a plate by the base 13 thereof.

The piezoelectric motor 10 further comprises a movable gear wheel 51 and two pawls 52, 53 configured to rotate the movable wheel 51 in a single direction. The movable wheel 51 preferably comprises a peripheral toothing, preferably asymmetrical toothing, which defines the direction of rotation. The movable wheel 51 is connected to a geartrain provided with hands of the display device.

The function of the first pawl 52 is to rotate the movable wheel 51 in a first direction, for example anti-clockwise, while the second pawl 53 retains the movable wheel 51 when the first pawl 52 is rewound on the next tooth of the rotor 51.

Each pawl 52, 53 includes a flexible arm 54 provided with a tooth 55, preferably asymmetrical, at the end thereof.

The rotation of the movable wheel 51 is generated thanks to the displacement of the first pawl 52. The first pawl 52 is mounted on the oscillating mass 12 of the piezoelectric resonator 10. Thus, when the resonator oscillates, the first pawl 52 also oscillates, such that it pushes or pulls the movable gear wheel 51 in a first direction according to the positioning of the piezoelectric resonator relative to the movable wheel 51.

The second pawl 53 is either assembled on the plate, a plate bridge, or directly on the base 30 to limit the positioning error due to the sequence of assembly tolerances. It has the function of preventing the gear wheel from turning in the direction opposite to the first direction. The tooth 55 of the second pawl 53 is configured to cooperate with the asymmetrical toothing, so as to let the movable wheel 51 rotate in the first direction, and to block it in the opposite direction.

To this end, the flexible arm 54 of the pawls 52, 53 are in the released straight position, when the tooth 55 is inserted into the toothing of the movable wheel 51, while it is wound and bent when it is pushed outwards by the teeth, when the movable wheel 51 rotates in the first direction.

In the case of a watch, the resonance frequency or natural frequency of motor 1 is adapted to the frequency of the quartz, which is used to set the rate of the movement. An excitation frequency is chosen, which corresponds to a sub-multiple of the quartz frequency, which is generally 32764 Hz. For example, a frequency of 128 Hz or 256 Hz is chosen. The frequency of the motor 1 is preferably adjusted and tuned to the excitation frequency such that its oscillation amplitude does not fall below 90-95% of the maximum amplitude.

Optionally, the second pawl 53 can be configured to be used as a pitch sensor, in order to determine the distance or the speed of rotation of the movable wheel 51. To this end, the flexible arm 54 of the second pawl 53 is equipped with a piezoelectric material connected to a counting unit. Thus, each time the second pawl 53 is bent, the counting unit records a rotation of the movable wheel 51 of a tooth.

It will be understood that various modifications and/or improvements and/or combinations obvious to the person skilled in the art may be made to the different embodiments of the invention set out above without departing from the scope of the invention defined by the appended claims.

1. A piezoelectric resonator for a rotary piezoelectric motor, the resonator comprising a stationary base and an oscillating mass extending about a longitudinal axis, the oscillating mass being provided with at least one inertia-block, preferably two opposing inertia blocks, wherein the resonator comprises a flexible blade guide connecting the oscillating mass to the base, so that the oscillating mass can be oscillated about a centre of rotation in a pendulum movement, the flexible guide comprising at least one first flexible blade connected to the base and/or to the oscillating mass to allow the displacement of the oscillating mass relative to the base, the flexible blade guide comprising a spiral spring connected to the base and/or to the oscillating mass, the spiral spring including at least partially an electrically actuatable piezoelectric material to deform the spiral spring and oscillate the oscillating mass.

2. The piezoelectric resonator according to claim 1, wherein the flexible guide includes a second flexible blade connecting the oscillating mass to the base, the first flexible blade connecting the base to the oscillating mass.

3. The piezoelectric resonator according to claim 2, wherein the first flexible blade and the second flexible blade are uncrossed and move away from each other from a central portion of the oscillating mass to eccentric portions of the base.

4. The piezoelectric resonator according to claim 2, wherein the first flexible blade and the second flexible blade are arranged to form an angle comprised between 30° and 150°.

5. The piezoelectric resonator according to claim 3, wherein the first flexible blade and the second flexible blade are arranged axially symmetrically relative to each other.

6. The piezoelectric resonator according to claim 2, wherein the spiral spring is connected to the oscillating mass to actuate the oscillation.

7. The piezoelectric resonator according to claim 1, wherein the flexible guide comprises two RCC type flexible pivots, the flexible guide being provided with an intermediate movable element, a first pair of flexible blades provided with the first flexible blade and a second flexible blade, the first pair of flexible blades connecting the base to the intermediate movable element, and a second pair of flexible blades, connecting the intermediate movable element to the oscillating mass.

8. The piezoelectric resonator according to claim 7, wherein the first flexible blade and the second flexible blade are uncrossed and move away from each other from the intermediate movable element to eccentric portions of the base.

9. The piezoelectric resonator according to claim 8, wherein the first flexible blade and the second flexible blade are arranged to form an angle comprised between 30° and 100°.

10. The piezoelectric resonator according to claim 6, wherein the first flexible blade and the second flexible blade are arranged axially symmetrically relative to each other.

11. The piezoelectric resonator according to claim 7, wherein the spiral spring is connected to the intermediate element and to the base, the spiral spring producing oscillation of the intermediate element when actuated.

12. The piezoelectric resonator according to claim 11, wherein the spiral spring is arranged between the first pair of flexible blades and the second pair of flexible blades.

13. The piezoelectric resonator according to claim 12, wherein the spiral spring and the first pair of flexible blades are arranged to form an angle comprised between 60° and 120°.

14. The piezoelectric resonator according to claim 12, wherein the spiral spring and the second pair of flexible blades are arranged to form an angle comprised between 20° and 60°.

15. The piezoelectric resonator according to claim 1, wherein the flexible guide comprises two RCC type flexible pivots, the flexible guide being provided with an intermediate movable element, a pair of flexible blades provided with the first flexible blade, the pair of flexible blades connecting the intermediate movable element to the oscillating mass, the spiral spring connecting the base to the intermediate movable element, the flexible guide comprising a second spiral spring connecting the base to the intermediate movable element, the second spiral spring including an electrically actuatable piezoelectric material to deform the second spiral spring and oscillate the oscillating mass.

16. The piezoelectric resonator according to claim 15, wherein the first spiral spring and the second spiral spring are arranged to form an angle comprised between 80° and 160°.

17. The piezoelectric resonator according to claim 15, wherein the first spiral spring and the second spiral spring are arranged axially symmetrically relative to each other.

18. The piezoelectric resonator according to claim 1, wherein the resonator is arranged substantially in the same plane.

19. The piezoelectric resonator according to claim 1, wherein the resonator is configured to oscillate the oscillating mass at the natural frequency of the resonator.

20. The piezoelectric resonator according to claim 1, including a non-magnetic monocrystalline or polycrystalline material and having low conductivity, such as silicon, glass, ceramic or a metal, and obtained for example by a MEMS-type photo-lithographic micromachining process.

21. A piezoelectric motor for a display device of a timepiece, the piezoelectric motor comprising a piezoelectric resonator according to claim 1.

22. The piezoelectric motor according to claim 21, comprising at least one pawl, and a movable wheel, the pawl being mounted on the oscillating mass of the piezoelectric resonator, so as to rotate the movable wheel in a first direction when the oscillating mass performs its oscillations.

23. A timepiece including a horological movement comprising a gear transmission configured to rotate at least one hand, wherein the timepiece comprises a piezoelectric resonator according to claim 1, the piezoelectric motor being arranged to actuate the gear transmission.
